(19) United States
(12) Patent Application Publication
(10) Pub. No.: US 2018/0108656 A1
(43) Pub. Date: Apr. 19, 2018

(54) ASYMMETRICAL FIN STRUCTURE AND METHOD OF FABRICATING THE SAME

(71) Applicant: UNITED MICROELECTRONICS CORP., Hsin-Chu City (TW)

(72) Inventors: Chao-Hung Lin, Changhua County (TW); Tong-Jyun Huang, Tainan City (TW); Shih-Hung Tsai, Tainan City (TW); Jyh-Shyang Jenq, Pingtung County (TW)

(21) Appl. No.: 15/347,797

(22) Filed: Nov. 10, 2016

(30) Foreign Application Priority Data
Oct. 18, 2016 (CN) 201610905131.3

(51) Int. Cl. H01L 27/088; H01L 29/78; H01L 29/161; H01L 21/8234; H01L 29/66; H01L 21/308; H01L 21/306; H01L 21/02; H01L 27/092

(52) U.S. Cl. CPC H01L 27/0886; H01L 29/7851; H01L 29/161; H01L 21/823431; H01L 21/823468; H01L 27/092; H01L 29/6656; H01L 21/3083; H01L 21/30604; H01L 21/02532; H01L 21/823437; H01L 29/66795

(57) ABSTRACT

An asymmetrical fin structure includes a substrate. The substrate includes a top surface. A fin element extends from the substrate and connects to the substrate. The fin element includes two sidewalls respectively disposed at two opposite sides of the fin element. The sidewalls contact the top surface of the substrate. An epitaxial layer contacts and only covers one of the sidewalls. The other sidewall on the fin element does not contact any epitaxial layer.

### BACKGROUND OF THE INVENTION

### 1. Field of the Invention

The present invention relates to an asymmetrical fin structure, and more particularly to an asymmetrical fin structure only having an epitaxial layer at one sidewall of a fin element.

### 2. Description of the Prior Art

Semiconductor devices are used in a large number of electronic devices, such as computers and cell phones. Semiconductor devices comprise integrated circuits that are formed on semiconductor wafers by depositing many types of thin film material over the semiconductor wafers, and patterning the thin films to form the integrated circuits. Integrated circuits include field-effect transistors (FETs) such as metal oxide semiconductor (MOS) transistors.

One of the goals of the semiconductor industry is to continue shrinking the size and increasing the speed of individual FETs. To achieve these goals, finFETs will be used in advanced transistor nodes. For example, FinFETs not only improve areal density but also improve gate control of the channel.

Therefore it is desirable to improve the fabricating process of FinFETs in order to obtain FinFETs with better quality.

### SUMMARY OF THE INVENTION

In accordance with one aspect of the embodiment, an asymmetrical fin structure includes a substrate having a top surface. A first fin element extends from the substrate and connects to the substrate, wherein the first fin element includes a first sidewall, and the first sidewall contacts the top surface. A first epitaxial layer contacts and only covers the first sidewall, wherein the first fin element and the first epitaxial layer form the asymmetrical fin structure.

In accordance with another aspect of the embodiment, a fabricating method of an asymmetrical fin structure includes the steps of providing a substrate. A first fin element and a second fin element are disposed on and extend from the substrate, wherein the first fin element and the second fin element are parallel, the first fin element includes a first sidewall, the second fin element includes a second sidewall, the first sidewall does not face the second fin element, and the second sidewall does not face the first fin element. Later, an epitaxial growth process is performed to form a first epitaxial layer only on the first sidewall and form a second epitaxial layer only on the second sidewall.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 4 and FIG. 6 to FIG. 9 depict a fabricating method of an asymmetrical fin structure according to a preferred embodiment of the present invention.

FIG. 5 shows steps of removing the mask layer according to another preferred embodiment of the present invention

FIG. 10 depicts a FinFET according to a preferred embodiment of the present invention.

### DETAILED DESCRIPTION

FIG. 1 to FIG. 4 and FIG. 6 to FIG. 9 depict a fabricating method of an asymmetrical fin structure according to a preferred embodiment of the present invention. As shown in FIG. 1, a substrate 10 is provided. The substrate 10 may be a bulk silicon substrate, a germanium substrate, a gallium arsenide substrate, a silicon germanium substrate, an indium phosphide substrate, a gallium nitride substrate, a silicon carbide substrate, or a silicon on insulator (SOI) substrate. A first region A is defined on the substrate 10. Numerous fin elements such as a first fin element 12, a second fin element 14, a third fin element 16 and a fourth fin element 18 arranged in sequence are disposed within the first region A on the substrate 10. Although there are four fin elements shown in FIG. 1, the number of the fin elements can be adjusted based on different product requirements. The material of the first fin element 12, the second fin element 14, the third fin element 16 and the fourth fin element 18 may be silicon or stacked epitaxial materials. The stacked epitaxial materials may be silicon germanium (SiGe), silicon carbide (SiC), silicon phosphide (SiP) or a combination thereof. The material of the first fin element 12, the second fin element 14, the third fin element 16 and the fourth fin element 18 is preferably silicon. The first fin element 12, the second fin element 14, the third fin element 16 and the fourth fin element 18 are parallel to each other. The first fin element 12, the second fin element 14, the third fin element 16 and the fourth fin element 18 all contact the substrate 10 and extend from the substrate 10. Advantageously, the material of forming the first fin element 12, the second fin element 14, the third fin element 16, the fourth fin element 18 and the substrate 10 are the same. A first cap layer 20, a second cap layer 22, a third cap layer 24 and a fourth cap layer 26 are respectively formed on the top surface of the first fin element 12, the top surface of the second fin element 14, the top surface of the third fin element 16, the top surface of the fourth fin element 18. The first cap layer 20, the second cap layer 22, the third cap layer 24 and the fourth cap layer 26 may be made of silicon nitride or silicon oxide. Furthermore, there are two different spaces between the fin elements. These two spaces are alternately disposed between the fin elements. A first space S1 may be disposed between the first fin element 12 and the second fin element 14. The first space S1 is also disposed between the third fin elements 16 and the fourth fin element 18. A second space S2 is disposed between the second fin element 14 and the third fin element 16. The first space S1 is smaller than the second space S2. According to a preferred embodiment of the present invention, the first space S1 is 11 nanometers. The second space S2 is 19 nanometers, but not limited thereto.

The first fin element 12 includes a first sidewall 112 and a fifth sidewall 212. The first sidewall 112 and the fifth sidewall 212 are respectively disposed at two opposing sides of the first fin element 12. The first sidewall 112 does not contact the fifth sidewall 212. The first sidewall 112 does not face the second fin element 14. The fifth sidewall faces 212 the second fin element 12. The first sidewall 112 contacts a top surface 11 of the substrate 10. The second fin element 14 includes a second sidewall 114 and a sixth sidewall 214. The second sidewall 114 and sixth sidewall 214 are respectively disposed at two opposing sides of the second fin element 14. The second sidewall 114 does not contact the sixth sidewall 214. The second sidewall 114 does not face the first fin element 12. The sixth sidewall 214 faces the first fin element 12. The second sidewall 114 contacts the top surface 11 of the substrate 10. Similarly, the third fin element 16 includes a third sidewall 116 and a seventh sidewall 216. The third sidewall 116 and the seventh sidewall 216 are respectively disposed at two opposing sides of the third fin element 16. The fourth fin element 18 includes a fourth sidewall 118 and an eighth sidewall 218. The fourth sidewall 118 and the eighth sidewall 218 are respectively disposed at two opposing sides of the fourth fin element 18. The third sidewall 116 does not face the fourth fin element 18. The fourth sidewall 118 does not face the third fin element 16. Later, a first insulating layer 28 is formed to blankly cover the substrate 10, the second fin element 14, the third fin element 16 and the fourth fin element 18. Subsequently, the first insulating layer 28 is planarized to be aligned with the top surface of the first cap layer 20. After that, a doping process is performed to form doped wells (not shown) within the first fin element 12, the second fin element 14, the third fin element 16 and the fourth fin element 18.

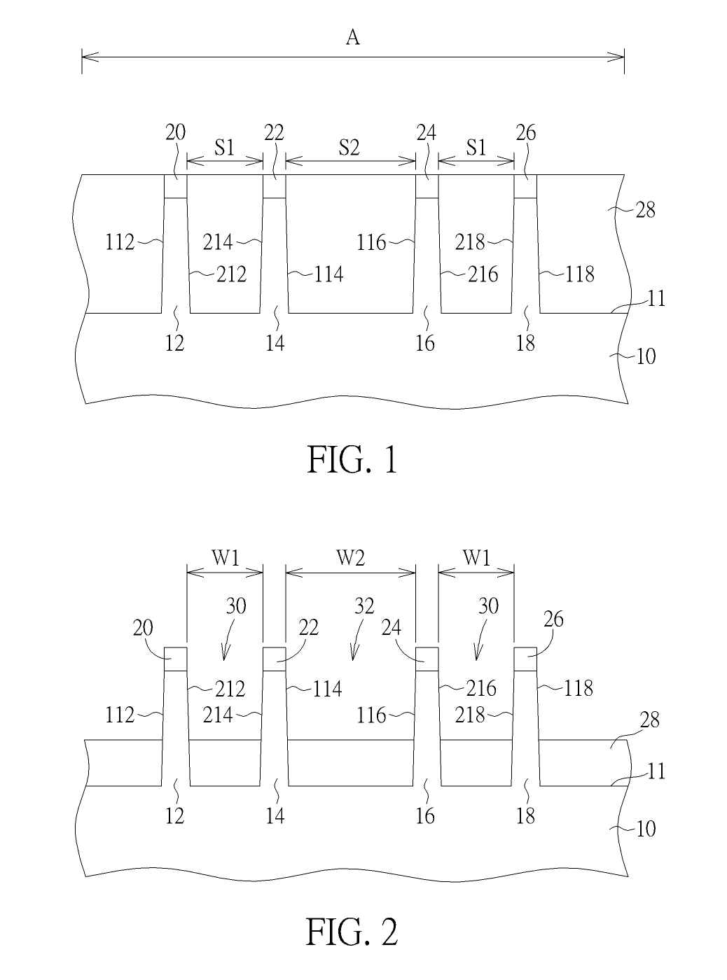

As shown in FIG. 2, part of the first insulating layer 28 is removed to expose part of the first fin element 12, part of the second fin element 14, part of the third fin element 16 and part of the fourth fin element 18. A first trench 30 is formed between the third fin element 16 and the fourth fin element 18. A second trench 32 is formed between the second fin element 14 and the third fin element 16. The width W2 of the second trench 32 is greater than the width W1 of the first trench 30. The step of removing the first insulating layer 28 may be a clean process or an etching process. For example, the step of removing the first insulating layer 28 may include removing the first insulating layer 28 within an ambient having ammonia and nitrogen trifluoride. Later, another doping process can be performed to implant dopants into the first fin element 12, the second fin element 14, the third fin element 16 and the fourth fin element 18 to adjust the threshold voltages of the first fin element 12, the second fin element 14, the third fin element 16 and the fourth fin element 18. According to a preferred embodiment of the present invention, the material of forming the first fin element 12, the second fin element 14, the third fin element 16 and the fourth fin element 18 are silicon. The doping process is for making the threshold voltage of silicon to approach the threshold voltage of silicon germanium. In this way, the threshold voltages of the first fin element 12, the second fin element 14, the third fin element 16 and the fourth fin element 18 can be compatible with the threshold voltage of the silicon germanium formed later.

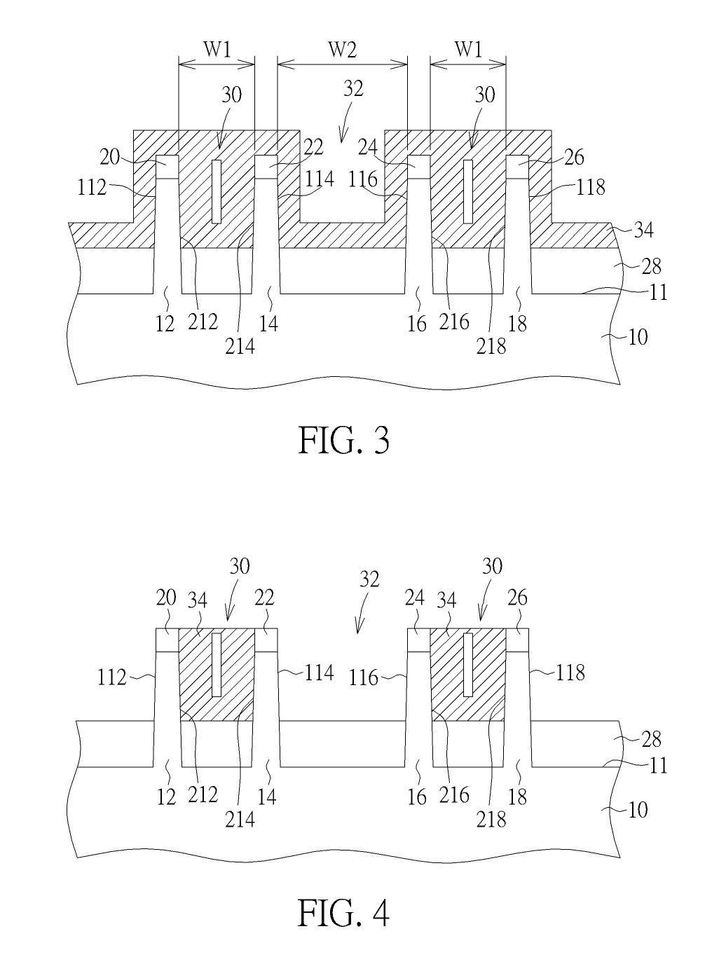

As shown in FIG. 3, a mask layer 34 is formed conformally to cover the first fin element 12, the second fin element 14, the third fin element 16, the fourth fin element 18 and the first insulating layer 28. The mask layer 34 also conformally covers the first trench 30 and the second trench 32. Because the width W1 of the trench 30 and the thickness of the mask layer 34 are specially designed, the opening of the trench 30 can be sealed up by the mask layer 34 when the mask layer 34 fills in the trench 30 conformally. A gap may be optionally formed in the mask layer 34 within the trench 30. In addition, because the width W2 of the second trench 32 is greater than the width W1, the opening of the second trench 32 is not sealed by the mask layer 34. The mask layer 34 can be silicon nitride. The method of forming the mask layer 34 may be a chemical vapor deposition process, a physical vapor deposition process or an atomic layer chemical vapor deposition process. According to a preferred embodiment of the present invention, the thickness of the mask layer 34 may be 55 angstroms, but not limited thereto.

As shown in FIG. 4, part of the mask layer 34 is removed anisotropically to expose the first sidewall 112, the second sidewall 114, the third sidewall 116 and the fourth sidewall 118. The mask layer 34 in the trench 30 remains. In detail, because the opening of the trench 30 is sealed by the mask layer 34 and the opening of the second trench 32 is open, the mask layer 34 in the trench 30 is kept during removal of the mask layer 34 outside of the trench 30, and the mask layer 34 in the second trench 32 is removed. The fifth sidewall 212, the sixth sidewall 214, the seventh sidewall 216 and the eighth sidewall 218 are not exposed and still covered by the mask layer 34. The first sidewall 112, the second sidewall 114, the third sidewall 116 and the fourth sidewall 118 are exposed. Therefore, one of the two opposing sidewalls on the first fin element 12 is exposed and the other is covered. Similarly, one of the two opposing sidewalls on the second fin element 14 is exposed and the other is covered. One of the two opposing sidewalls on the third fin element 16 is exposed and the other is covered. One of the two opposing sidewalls on the fourth fin element 18 is exposed and the other is covered

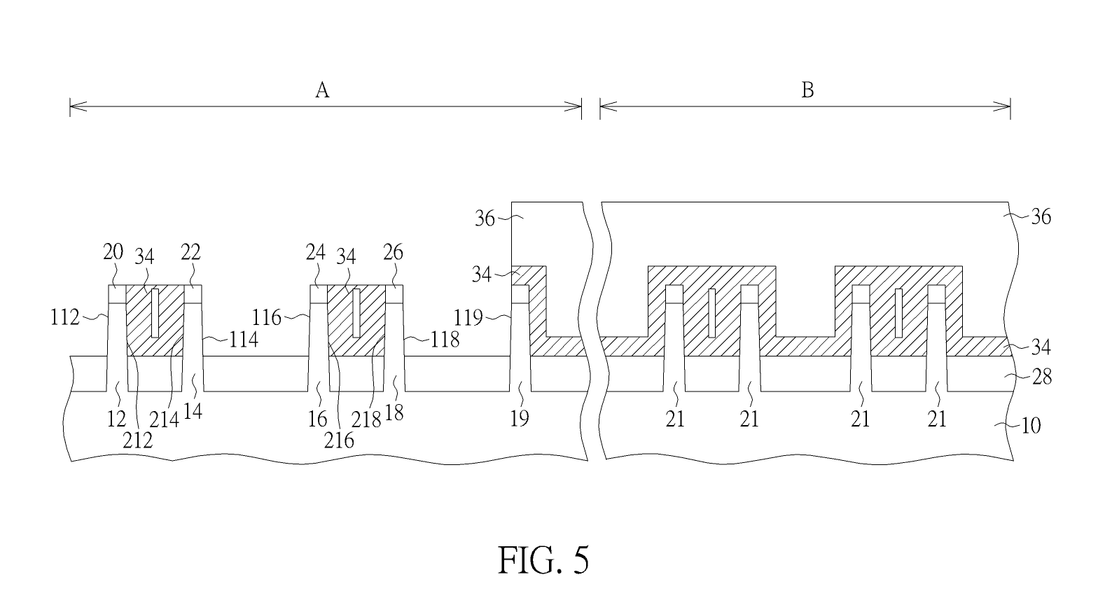

FIG. 5 shows steps of removing the mask layer according to another preferred embodiment of the present invention, wherein like reference numerals are used to refer to like elements throughout. FIG. 5 continues from FIG. 3. As shown in FIG. 5, in this embodiment, the substrate 10 is defined into a first region A and a second region B. The first region A is a PMOS region or an NMOS region and the second region B is an NMOS region or a PMOS region. The number of the fin elements in the first region A is an odd number. Please refer to FIG. 4 and FIG. 5 together. In order to make one sidewall covered by the mask layer 34 while the other sidewall is exposed, the total number of the fin elements should be an even number so that the fin elements can be divided into pairs. Then, the mask layer 34 can seal the opening of a trench formed by the pairing fin elements. If the number of fin elements in the first region A is an odd number, there must be a fin element 19 not having its match. Generally, the sole fin element 19 is at the edge of the first region A and near to the second region B. Under this circumstance, an extra protective layer 36 should be formed to cover part of the fin element 19. Then, the mask layer 34 can be anisotropically removed. Moreover, because the fin elements 21 in the second region B have different fabricating processes from that of the fin elements in the first region A, the protective layer 36 will also cover the fin elements 21 within the second region B before anisotropic removal of part of the mask layer 34. Therefore, as shown in FIG. 5, the protective layer 36 is formed to cover part of the fin element 19 and the second region B. Then, the mask layer 34 is anisotropically removed to expose the first sidewall 112, the second sidewall 114, the third sidewall 116, the fourth sidewall 118 and a sidewall 119 of the fin element 19. After that, the protective layer 36 is removed. The difference between FIG. 4 and FIG. 5 is that in FIG. 5, there are numerous fin elements 21 in the second region B and the fin element 19 is added in the first region A. The fabricating steps of FIG. 5 performed afterwards are the same as those in FIG. 4.

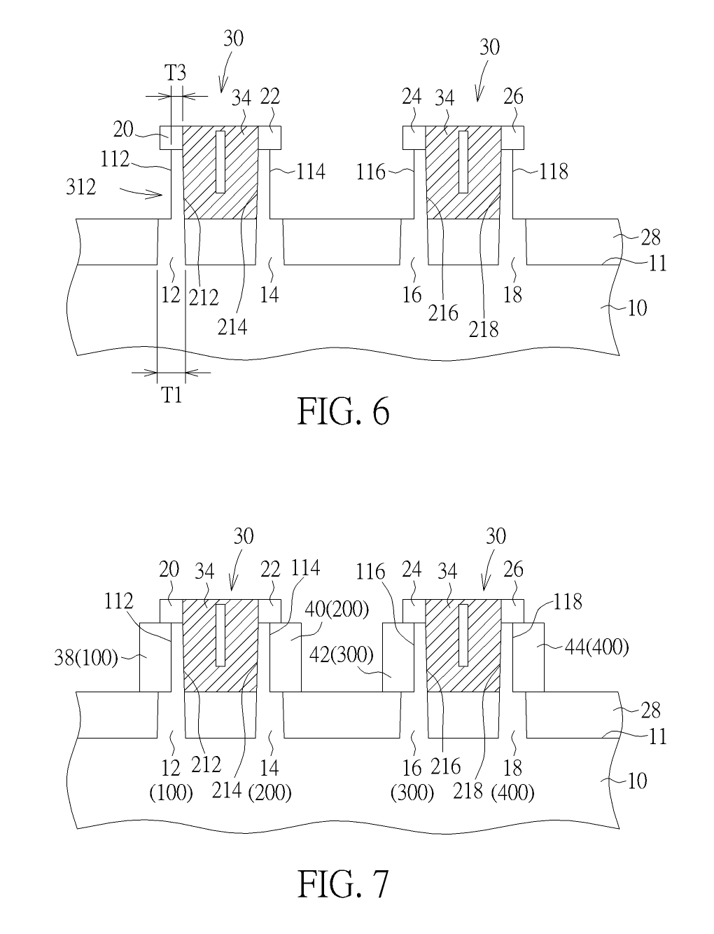

FIG. 6 continues from FIG. 4. As shown in FIG. 6, the first fin element 12, the second fin element 14, the third fin element 16 and the fourth fin element 18 are optionally thinned in a thinning process. After the thinning process, the first fin element 12 in the first insulating layer 28 has a first thickness T1. The first fin element 12 outside of the first insulating layer 28 has a third thickness T3. The first thickness T1 is greater than the third thickness T3. Moreover, after the thinning process, a step profile is formed on the first sidewall 112 of the first fin element 12. In other words, a recess 312 is on the first sidewall, and the fifth sidewall is a planar profile without recess. Similarly, after the thinning process, the thickness of the second fin element 14 in the first insulating layer 28, the thickness of the third fin element 16 in the first insulating layer 28, and the thickness of the fourth fin element 18 in the first insulating layer 28 are greater than the thickness of the second fin element 14 outside of the first insulating layer 28, the thickness of the third fin element 16 outside of the first insulating layer 28, and the thickness of the fourth fin element 18 outside of the first insulating layer 28. There is a recess respectively on the second sidewall 114, the third sidewall 116 and the fourth sidewall 118.

As shown in FIG. 7, an epitaxial growth process is performed to form a first epitaxial layer 38 only on the first sidewall 112, a second epitaxial layer 40 only on the second sidewall 114, a third epitaxial layer 42 only on the third sidewall 116 and a fourth epitaxial layer 44 only on the fourth sidewall 118. It is noteworthy that, because the mask layer 34 still covers the first trench 30, there is no epitaxial layer form on the fifth sidewall 212, the sixth sidewall 214, the seventh sidewall 216 and the eighth sidewall 218. At this point, the asymmetrical fin structure of the present invention is completed. The first fin element 12 and the first epitaxial layer 38 form an asymmetrical fin structure 100. The second fin element 14 and the second epitaxial layer 40 form an asymmetrical fin structure 200. The third fin element 16 and the third epitaxial layer 42 form an asymmetrical fin structure 300. The fourth fin element 18 and the fourth epitaxial layer 44 form an asymmetrical fin structure 400. Moreover, the protective layer 36 in FIG. 5 can be removed after the epitaxial growth process is completed. The first epitaxial layer 38, the second epitaxial layer 40, the third epitaxial layer 42, the fourth epitaxial layer 44 can be made of the same or different material than the material which forms the first fin element 12, the second fin element 14, the third fin element 16 and the fourth fin element 18. For example, the first epitaxial layer 38, the second epitaxial layer 40, the third epitaxial layer 42, the fourth epitaxial layer 44 can be made of silicon germanium (SiGe), silicon carbide (SiC), silicon phosphide (SiP) or a combination thereof. In this embodiment, the first epitaxial layer 38, the second epitaxial layer 40, the third epitaxial layer 42, the fourth epitaxial layer 44 are formed by a material different from a material forming the first fin element 12, the second fin element 14, the third fin element 16 and the fourth fin element 18. The material of forming the first epitaxial layer 38, the second epitaxial layer 40, the third epitaxial layer 42, and the fourth epitaxial layer 44 is preferably silicon germanium (SiGe). The material of forming the first fin element 12, the second fin element 14, the third fin element 16 and the fourth fin element 18 is preferably silicon.

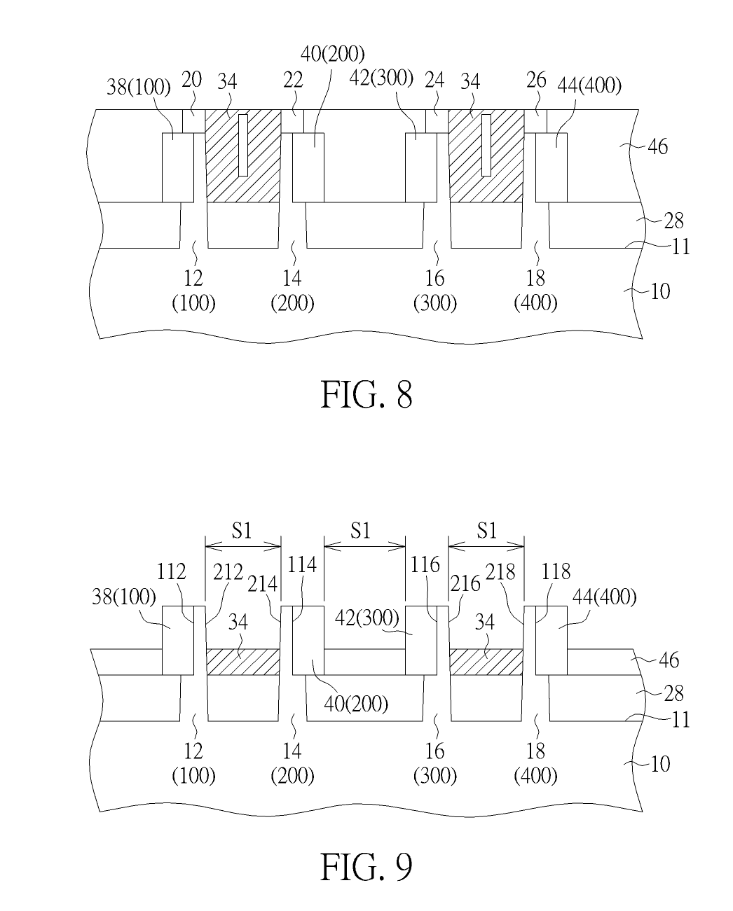

As shown in FIG. 8, a second insulating layer 46 is formed to cover the first insulating layer 28. Then, the second insulating layer 46 is planarized to be aligned with the top surface of the first cap layer 20. As shown in FIG. 9, part of the second insulating layer 46, part of the mask layer 34, the entire first cap layer 20, the entire second cap layer 22, the entire third cap layer 24 and the entire fourth cap layer 26 are removed to expose part of the first epitaxial layer 38, part of the second epitaxial layer 40, part of the third epitaxial layer 42, and part of the fourth epitaxial layer 44. At this point, the space between the second epitaxial layer 40 and the third epitaxial layer 42 is the first space S1. The space between the second epitaxial layer 40 and the third epitaxial layer 42, and the space between the first fin element 12 and the second fin element 14 are the same.

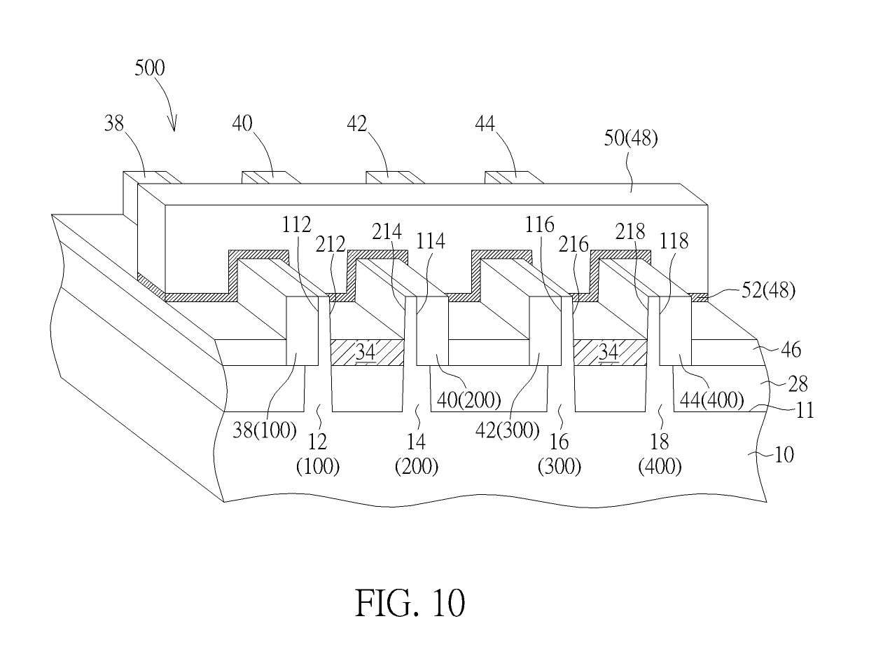

FIG. 10 depicts a FinFET according to a preferred embodiment of the present invention, wherein like reference numerals are used to refer to like elements throughout. As shown in FIG. 10, a gate structure 48 is formed to cross the asymmetrical fin structures 100/200/300/400. The gate structure 48 includes a polysilicon gate 50 and a gate dielectric layer 52. Then, source/drain doped regions (not shown) are formed in the first fin element 12, the second fin element 14, the third fin element 16 and the fourth fin element 18. At this point, the first fin element 12, the first epitaxial layer 38, the gate structure 48 and the source/drain doped regions form a FinFET 500. The second fin element 14, the third fin element 16, the fourth fin element 18, the second epitaxial layer 40, the third epitaxial layer 42, the fourth epitaxial layer 44, the gate structure 48 and the source/drain doped regions respectively form FinFETs. Taking the FinFET 500 as an example, when the FinFET 500 is turned on, part of the channel is formed in the first fin element 12, and the other part of the channel is formed in the first epitaxial layer 38. Because the material of forming the first fin element 12 is preferably silicon, and the material of forming the first epitaxial layer 38 is preferably silicon germanium, the threshold voltage of the first fin element 12 is adjusted in the step shown in FIG. 2 to tune the threshold voltage of silicon to approach the threshold voltage of silicon germanium.

Furthermore, in the following process, the polysilicon gate 50 can be replaced by a metal electrode. Before forming the metal electrode, a high-k dielectric layer and a work function layer can be formed to cross each of the symmetrical fin structures 100/200/300/400. According to a preferred embodiment of the present invention, the FinFET 500 is preferably a p-type FinFET.

FIG. 9 depicts a set of asymmetrical fin structures, wherein like reference numerals are used to refer to like elements throughout. The set of asymmetrical fin structures can include single or plural asymmetrical fin structures. As shown in FIG. 9, a set of the asymmetrical fin structures includes a symmetrical fin structure 100. The symmetrical fin structure 100 includes a substrate 10. The substrate 10 includes a top surface 11. A first fin element 12 extends from the substrate 10 and contacts the substrate 10. The set of asymmetrical fin structures can optionally further include an asymmetrical fin structure 200. The symmetrical fin structure 200 includes a second fin element 14 extending from the substrate 10 and connecting to the substrate 10. The first fin element fin 12 and the second fin element 14 are parallel. The first fin element 12 includes a first sidewall 112. The first sidewall 112 contacts the top surface 11 of the substrate 10. A first epitaxial layer 38 contacts and only covers part of the first sidewall 112 of the first fin element 12. The material of forming the first fin element 12 is different from a material of forming the first epitaxial layer 38. The second fin element 14 includes a second sidewall 114. The second sidewall 114 contacts the top surface 11 and is optionally parallel to the first sidewall 112. A second epitaxial layer 40 contacts and only covers part of the second sidewall 114 of the second fin element 14. The material of forming the second fin element 14 is different from a material of forming the second epitaxial layer 40. Furthermore, the first sidewall 112 does not face the second fin element 114. The second sidewall 114 does not face the first fin element 12. The substrate 10 may be a bulk silicon substrate, a germanium substrate, a gallium arsenide substrate, a silicon germanium substrate, an indium phosphide substrate, a gallium nitride substrate, a silicon carbide substrate, or a silicon on insulator (SOI) substrate. The material of making the first fin element 12 is the same as that of the second fin element 14. According to a preferred embodiment of the present invention, the material of forming the first fin element 12 and the second fin element 14 are both silicon. The substrate 10 is preferably silicon. Therefore, the material of forming the first fin element 12, the second fin element 14 and the substrate 10 are the same. The material of forming the first epitaxial layer 38 and the second epitaxial layer 40 are the same. Advantageously, the first epitaxial layer 38 and the second epitaxial layer 40 are silicon germanium. In other embodiment, the substrate 10, the first fin element 12 and the second fin element 14 can be formed by different materials. It is noteworthy that the first fin element 12 further includes a fifth sidewall 212. The first sidewall 112 and the fifth sidewall are preferably parallel. The first sidewall 112 and the fifth sidewall 212 are respectively disposed at two opposing sides of the first fin element 12. The first sidewall 112 does not contact the fifth sidewall 212. The fifth sidewall 212 does not contact any epitaxial layer, and more specifically, the fifth sidewall 212 does not contact silicon germanium. In addition, the second fin element 14 further includes a sixth sidewall 214. The second sidewall 114 and the sixth sidewall 214 are preferably parallel. The second sidewall 114 and the sixth sidewall 214 are respectively disposed at two opposing sides of the second fin element 14. The second sidewall 114 does not contact the sixth sidewall 214. The sixth sidewall 214 does not contact any epitaxial layer, and more specifically, the sixth sidewall 214 does not contact silicon germanium. Moreover, the fifth sidewall 212 faces the second fin element 14. The sixth sidewall faces the first fin element 12. The fifth sidewall 212 faces the sixth sidewall 214.

The first fin element 12 and the first epitaxial layer 38 form an asymmetrical fin structure 100. The second fin element 14 and the second epitaxial layer 40 form an asymmetrical fin structure 200. The asymmetrical fin structure 100 and the asymmetrical fin structure 200 form a set of the asymmetrical fin structures. In detail, the profile of the asymmetrical fin structure 100 is asymmetrical. For example, the first sidewall 112 of the first fin element 12 has a first epitaxial layer 38. The fifth sidewall 212 of the first fin element 12 does not have the first epitaxial layer 38, however. If the asymmetrical fin structure 100 is symmetrical, both the first sidewall 112 and the fifth sidewall 212 should have the first epitaxial layer 38. The asymmetrical fin structure 200 has the same asymmetrical profile as that of the asymmetrical fin structure 100. The set of asymmetrical fin structures can be repeated on the substrate 10 several times. For example, the substrate 10 can further include an asymmetrical fin structure 300 and an asymmetrical fin structure 400. The structure of the asymmetrical fin structure 100 is basically the same as the asymmetrical fin structure 300. The structure of the asymmetrical fin structure 200 is basically the same as the asymmetrical fin structure 400. The asymmetrical fin structure 300 and the asymmetrical fin structure 400 form another set of the asymmetrical fin structures. The third fin element 16 and the third epitaxial layer 42 form the asymmetrical fin structure 300. The fourth fin element 18 and the fourth epitaxial layer 44 form the asymmetrical fin structure 400. It is noteworthy that the space between the third epitaxial layer 42 and the second epitaxial layer 40 is a first space S1. The space between the first fin epitaxial layer 12 and the second fin epitaxial layer 14 is also the first space S1. The space between the first fin element 12 and the second fin element 14 is the same as the space between the third epitaxial layer 42 and the second epitaxial layer 40. Moreover, the profile of the asymmetrical fin structure 100 is like a flag plus a flag pole. The first fin element 12 is like the flag, and the first epitaxial layer 38 is like the flag pole. Therefore, the asymmetrical fin structure 100 is asymmetrical. Only one sidewall of the first fin element 12 has the first epitaxial layer 38. Similarly, the asymmetrical fin structures 200/300/400 respectively form profiles having a flag plus a flagpole. The asymmetrical fin structures 200/300/400 are also asymmetrical. A first insulating layer 28 is between the first fin element 12 and the second fin element 14. A mask layer 34 is between the first fin element 12 and the second fin element 14. The mask layer 34 covers the first insulating layer 28. The first insulating layer 28 and the mask layer 34 do not contact the first epitaxial layer 38 and the second epitaxial layer 40. The first insulating layer 28 and the mask layer 34 are preferably silicon oxide. The set of the asymmetrical fin structures of the present invention can be applied to a FinFET 500. As shown in FIG. 10, a gate structure 48 crosses the contacts the asymmetrical fin structure 100 formed by the first fin element 12 and the first epitaxial layer 38. The gate structure 48 can also cross the asymmetrical fin structure 200 formed by the second fin element 14 and the second epitaxial layer 40, the asymmetrical fin structure 300 formed by the third fin element 16 and the third epitaxial layer 42, and the asymmetrical fin structure 400 formed by the fourth fin element 18 and the fourth epitaxial layer 44. The gate structure 48 includes a polysilicon gate 50 and a gate dielectric layer 52.

Based on the present invention, only one sidewall of a fin element has an epitaxial layer thereon. In conventional methods, there is usually an epitaxial layer wrapping up three walls of a fin element. By using the method and the structure of the present invention, the epitaxial layer will not occupy too much space between the fin elements. In this way, the work function layer can be conformally filled into the space between the fin elements.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An asymmetrical fin structure, comprising:
a substrate comprising a top surface;
a first fin element extending from the substrate and connecting to the substrate, wherein the first fin element comprises a first sidewall, and the first sidewall contacts the top surface; and
a first epitaxial layer contacting and only covering the first sidewall, wherein the first fin element and the first epitaxial layer form the asymmetrical fin structure.

2. The asymmetrical fin structure of claim 1, wherein the first fin element is formed by a first material different from a second material which forms the first epitaxial layer.

3. The asymmetrical fin structure of claim 1, further comprising a third sidewall disposed on the first fin element, wherein the third sidewall and the first sidewall are respectively at two opposing sides of the first fin element, and the third epitaxial layer does not contact any epitaxial layer.

4. The asymmetrical fin structure of claim 1, further comprising:
a second fin element extending from the substrate and connecting to the substrate, wherein the first fin element and the second fin element are parallel, and the second fin element comprises a second sidewall contacting the top surface; and
a second epitaxial layer contacting and only covering part of the second sidewall, wherein the second fin element is formed by a third material different from a fourth material which forms the second epitaxial layer.

5. The asymmetrical fin structure of claim 4, further comprising a fourth sidewall disposed on the second fin element, wherein the second sidewall and the fourth sidewall are respectively at two opposing sides of the second fin element, and the fourth epitaxial layer does not contact any epitaxial layer.

6. The asymmetrical fin structure of claim 4, wherein the second sidewall does not face the first fin element.

7. The asymmetrical fin structure of claim 4, further comprising an insulating layer disposed between the first fin element and the second fin element, wherein the insulating layer does not contact the first epitaxial layer and the second epitaxial layer.

8. The asymmetrical fin structure of claim 1, wherein the first fin element is made of silicon and the first epitaxial layer is made of silicon-germanium.

9. The asymmetrical fin structure of claim 1, further comprising a gate structure crossing the first fin element.

10. The asymmetrical fin structure of claim 1, wherein the first fin element and the substrate are made of the same material.

11. A fabricating method of an asymmetrical fin structure, comprising:
providing a substrate, a first fin element and a second fin element disposed on and extending from the substrate, wherein the first fin element and the second fin element are parallel, the first fin element comprises a first sidewall, the second fin element comprises a second sidewall, the first sidewall does not face the second fin element, and the second sidewall does not face the first fin element; and
performing a epitaxial growth process to forma first epitaxial layer only on the first sidewall and form a second epitaxial layer only on the second sidewall.

12. The fabricating method of an asymmetrical fin structure of claim 11, wherein further comprises the steps of:
before the epitaxial growth process, forming a first cap layer on the first fin element and forming a second cap layer on the second fin element;
forming a first insulating layer to cover the substrate, the first fin element and the second fin element, wherein the first insulating layer is aligned with a top surface of the first cap layer;
removing part of the first insulating layer to expose part of the first fin element and part of the second fin element and form a trench between the first fin element and the second fin element;
forming a mask layer conformally covering the first fin element, the second fin element and the first insulating layer, wherein the mask layer seals an opening of the trench; and
anisotropically removing part of the mask layer to expose the first sidewall and the second sidewall and leaving the mask layer in the trench.

13. The fabricating method of an asymmetrical fin structure of claim 12, further comprising:
after removing part of the mask layer and before performing the epitaxial growth process, thinning the exposed first fin element and the exposed second fin element.

14. The fabricating method of an asymmetrical fin structure of claim 12, further comprising:
after forming the first epitaxial layer and the second epitaxial layer, forming a second insulating layer to cover the first insulating layer, wherein the second insulating layer is aligned with the top surface of the first cap layer;
removing part of the second insulating layer and part of the mask layer to expose at least part of the first epitaxial layer and at least part of the second epitaxial layer; and
forming a gate structure crossing the first fin element, the second fin element, the first epitaxial layer and the second epitaxial layer.

15. The fabricating method of an asymmetrical fin structure of claim 11, further comprising a third fin element and a fourth fin element extending from the substrate, the first fin element, the second fin element, the third fin element and the fourth fin element arranged in sequence, the third fin element comprising a third sidewall, and the fourth fin element comprising a fourth sidewall, wherein the third sidewall does not face the fourth fin element, and the fourth sidewall does not face the third fin element.

16. The fabricating method of an asymmetrical fin structure of claim 15, further comprising simultaneously forming a third epitaxial layer and a fourth epitaxial layer respectively on the third sidewall and on the fourth sidewall during the epitaxial growth process.

17. The fabricating method of an asymmetrical fin structure of claim 16, wherein a first space is disposed between the first fin element and the second fin element and the first space is also disposed between the second epitaxial layer and the third epitaxial layer.

18. The fabricating method of an asymmetrical fin structure of claim 17, wherein a first space is disposed between the first fin element and the second fin element, a second space is disposed between the second fin element and the third fin element, the first space is also disposed between the third fin element and the fourth fin element, and the first space is smaller than the second space.
